(19) United States
(12) Patent Application Publication
(10) Pub. No.: US 2009/0217876 A1
(43) Pub. Date: Sep. 3, 2009

(54) Coating System For A Ceramic Evaporator Boat

(75) Inventor: Jeffrey Stephen Epstein, Houston, TX (US)

Correspondence Address: STREETS & STEELE, 13831 NORTHWEST FREEWAY, SUITE 355, HOUSTON, TX, 77040, US

(73) Assignee: CERAMIC TECHNOLOGIES, INC., Houston, TX (US)

(21) Appl. No.: 12/039,153

(22) Filed: Feb. 28, 2008

(51) Int. Cl. C23C 16/448; C23C 14/56; C23C 16/10

(52) U.S. Cl. 118/726; 392/389; 204/192.16; 427/255.36

(57) ABSTRACT

A coating system is applied to a ceramic evaporator boat to extend the life of the boat. The coating system includes a ceramic layer is applied over the surface of an evaporator boat reservoir. Optionally, a refractory metal layer is applied as an intermediate layer between the surface of the evaporator boat reservoir and the ceramic layer. The ceramic layer is form of a ceramic material selected from metal borides, metal nitrides, metal carbides, metal oxides, and combinations thereof, and wherein the metal component of the ceramic material is selected from zirconium, aluminum, titanium, silicon, tantalum, vanadium, and combinations thereof. The resulting coating system reduces corrosion and/or erosion that occur primarily in the reservoir region of the evaporator boat. One method of applying or depositing the ceramic layer or the optional refractory metal layer includes sputtering.

### BACKGROUND OF THE INVENTION

1. Field of the Invention

The present invention relates to evaporator boats used in vapor deposition and, more specifically, used in vacuum metallization.

2. Background of the Related Art

Evaporator boats are used as containment vessels and electrical resistance heaters to melt and vaporize metals in the metallizing industry. Typical evaporator boats are made from a composite of boron nitride (BN), Titanium Diboride (TiB₂) and/or Aluminum Nitride (AlN). These boats may also be referred to as Inter-Metallic-Composite (IMC) evaporator boats. The heating element should be resistant to the corrosive and erosive effects of the metal in both the molten and vapor states. Evaporator boats are often rectangular and trough-shaped. Series evaporators are typically provided with clamping surfaces on their two vertical ends or narrow sides in order to be supported on a boat holder.

U.S. Pat. No. 5,242,500 discloses an apparatus for the continuous coating of strip-shaped substrates in a vacuum coating chamber with a plurality of evaporator boats of approximately the same size and configuration, in which the boats are parallel to each other and approximately equal distances apart in the direction of strip travel to form an evaporator bank. The evaporator boats are also made of an electrically conductive ceramic and can be heated by the direct passage of current. The apparatus also has a device which continuously feeds a wire to the evaporator boats for evaporation. The individual evaporator boats are staggered with respect to each other, and all the evaporator boats together cover a narrow substrate-coating zone, which is crosswise to the direction of strip travel. The staggered arrangement is intended to reduce the interaction between the individual sources and thus to improve the uniformity of the coating. The individual evaporator boats themselves have a rectangular cross section, and the recesses which hold the molten material all have a rectangular outline.

DE 970 246 discloses an ceramic, resistance heated evaporation boat for the continuous deposition of coatings from the vapor phase on endless substrate strips with several directly heated evaporators arranged in a row. The boat is designed to eliminate a disadvantage of the conventional type of evaporator with a rectangular outline for a recess, which arises from the fact that the evaporating material, which is an excellent conductor of electrical current, short-circuits the evaporator to some extent so that only the parts of the evaporator between the individual recesses serve as heat generators, which means than a non-uniform coating is produced. Accordingly, the cross section of the evaporator between the individual recesses is reduced, so that the electrical resistance of the evaporator is approximately constant and independent of the amount of evaporating material that is present.

This older series evaporator solves the problem of how to clamp the evaporators in pairs between the electric feed lines and how to ensure good electrical contact during the evaporation process. But even with this pairwise arrangement of the evaporators, the problem of obtaining coatings of optimum uniformity is not yet completely solved.

U.S. Pat. No. 5,261,964 discloses an evaporator boat consisting of a flat, trough-shaped part of electrically conductive material. The boat can be heated by the direct passage of current through it, and it has an essentially rhombic or rhomboidal outline. The configuration of the recess is approximately the same as that of the boat. Two diametrically opposite corners of the evaporator boat are each provided with a flattened, approximately rectangular, vertical area, the two of which together form the parallel clamping surfaces of the evaporator boat.

In an Oct. 10, 2007 conference paper entitled “Changes to an IMC Evaporator during Aluminum Metalization”, Michael Nurnberger states that, during aluminum metallization using an evaporator boat, aluminum nitride is produced by a reaction between boron nitride and liquid aluminum. Titanium diboride in the composite ceramic of the boat gets dissolved in the molten aluminum and is re-crystalized at the ends of the boat where slag builds up. The AlN also forms an intermediate layer between the puddle of liquid aluminum and the core composite ceramic. This intermediate reaction layer acts as a passive layer which tends to protect the core ceramic.

Evaporator boats may also be made with a composite of boron nitride (BN) and titanium diboride (TiB₂) and coated with a TiCuAl alloy. This alloy enhances the boat's wettability and enlarges the puddle size. The coating also allows for metallization of copper and other metals. Enhanced wettability may also be imparted by using flow channels or laser engraved marks in the evaporator boat reservoir.

### SUMMARY OF THE INVENTION

One embodiment of the invention provides an improved evaporator boat comprising a boat body including an electrically conductive ceramic, wherein the boat body forms a reservoir for holding a puddle of liquid metal for evaporation, and a ceramic layer formed over the reservoir surface. The ceramic layer is formed of a ceramic material selected from metal borides, metal nitrides, metal carbides, metal oxides, and combinations thereof, wherein the metal component of the ceramic material is selected from zirconium, aluminum, titanium, silicon, tantalum, vanadium, and combinations thereof. Presently preferred materials for the ceramic layer include aluminum oxide and titanium diboride.

Another embodiment of the invention provides an improved evaporator boat comprising a boat body including an electrically conductive ceramic, wherein the boat body forms a reservoir for holding a puddle of liquid metal for evaporation, a refractory metal layer formed over the reservoir surface, and a ceramic layer formed over the refractory metal layer. The refractory metal layer is selected from titanium, scandium, vanadium, chromium, manganese, yttrium, zirconium, niobium, molybdenum, technetium, haffiium, tantalum, tungsten, rhenium, combinations thereof, and alloys thereof. A presently preferred refractory metal is chromium. The ceramic layer is formed of a ceramic material selected from metal borides, metal nitrides, metal carbides, metal oxides, and combinations thereof, wherein the metal component of the ceramic material is selected from zirconium, aluminum, titanium, silicon, tantalum, vanadium, and combinations thereof. Presently preferred materials for the ceramic layer include aluminum oxide and titanium diboride.

Another embodiment of the invention provides a method comprising depositing a layer of a refractory metal over the surface of a reservoir formed in an evaporator boat, and depositing a layer of a ceramic over the refractory metal layer. A preferred process for depositing the refractory metal layer and the ceramic layer is sputtering.

### BRIEF DESCRIPTION OF THE DRAWINGS

FIG. 1 is a perspective view of a ceramic evaporator boat

### DETAILED DESCRIPTION OF THE INVENTION

One embodiment of the invention is directed to a coating system that is applied to a ceramic evaporator boat to extend the life of the boat. The coating system includes a ceramic layer applied over a surface of the ceramic evaporator boat to slow or minimize corrosion and/or erosion that occurs primarily in the reservoir region of the evaporator boat. For example, corrosion can occur when the metal to be evaporated is aluminum and the molten aluminum (Al) reacts with boron nitride (BN) in the ceramic evaporator boat body.

The ceramic layer may be applied directly over the evaporator boat body. The ceramic layer may have a thickness of between 1.5 microns and 0.010 (1/100) inch, and preferably between 2 microns and 5 microns. However, a ceramic layer will most preferably have a uniform thickness averaging between 1.5 and 3 microns. The ceramic layer is suitably made of a ceramic material selected from a metal boride, metal nitride, metal carbide, metal oxide, and combinations thereof, where the metal is selected from zirconium (Zr), aluminum (Al), titanium (Ti), silicon (Si), tantalum (Ta), vanadium (V), and combinations thereof.

The material of the ceramic layer has a different composition than the ceramic of the evaporator boat body, and may be selected for its corrosion resistance and hardness. A corrosion resistant ceramic material is one that does not readily react with the molten metal in the reservoir. Accordingly, the ceramic material preferably does not contain boron nitride (BN) when the metal being evaporated is aluminum. A hard ceramic material can withstand greater wear during evaporation of metal. The surface of the boat reservoir experiences minor explosions as air bubbles burst within the molten aluminum and blast away grains of the ceramic. The free ceramic grains either join the volume of slag or undesirably adhere to the substrate during metallization. In effect, the molten metal has to wear through the coating system before the molten metal begins degrading the base substrate of the boat. Still further, a ceramic material having a high wettability, or at least a wettability greater than that of the evaporator boat body, will yield a larger metal puddle in the boat reservoir, which in turn keeps the boat cooler and reduces the rate of corrosion. As the operating temperature of the boat increases, kinetics of the chemical reaction taking place increase, thereby making the boat further erode and corrode.

The coating system of the present invention provides the significant advantage of extending the boat life above the 8 to 12 hour average boat life of an uncoated evaporator boat. However, embodiments of the coating system described herein also enable the evaporator boat to be optimized primarily for its electrical resistance heating properties without regard to corrosion and wear resistance.

It is believed that the coating system reduces corrosion reactions that may occur during a metallization process by sealing the surface porosity of the ceramic evaporator boat. Effectively, the molten aluminum or other molten metal has to wear through the coating system before it can start corroding the BN substrate. In addition to minimizing the rate of corrosion, applying a layer of a hard ceramic to the boat surface can significantly increase the surface hardness of the boat. As the hardness of the boat increases, the wear resistance of the boat also increases. A typical evaporator boat composition is, for example, a composite of 70% BN and 30% TiB₂. Boron nitride (BN) is a very soft ceramic (400 kilograms-force per millimeter (kgf/mm) using the Knoop hardness test) with poor wear resistance. Increasing the surface hardness to 3000 (kgf/mm) with a hard ceramic layer protects this soft matrix from wear and corrosion, and extends the longevity of the boat. The longevity of a boat (“boat life”) is affected by many variables including, but not limited to, proper clamping, MOC matching between the evaporator boat and the metallizer power supply, puddle size, use temperature and wire feeding location.

The ceramic layer of the coating system is preferably also selected to minimize slag formation on the boat reservoir surface during metallization. Because the coating system prevents or minimizes the reaction between BN in the evaporator boat body and liquid Al contained in the reservoir, the amount of the primary component of slag (i.e., AlN) will be reduced. The prevention of slag is a second mechanism by which the coating system increases the boat life. Because slag does not create a “dam effect” at the ends of the boat cavity, the size of the aluminum puddle does not shrink, and amount of metal evaporation is maintained. As the puddle size decreases, the temperature of the boat increases. In fact, a large aluminum puddle keeps the boats cooler and a small puddle elevates the temperature of the boats. As the temperature of the boat increases, the reaction kinetics of the corrosion mechanism also increase.

Another embodiment of the invention provides a coating system comprising a refractory metal layer applied directly to the surface of the evaporator boat, and a subsequently ceramic layer is applied over the refractory metal layer. Refractory metals do not melt at the process temperatures typically encountered in metallization process, for example ranging from 1450 to 1550 degrees Celsius, and provide a good bond between the ceramic body of the evaporator boat and the ceramic layer. The refractory metal layer may have a thickness of between 100 Angstroms and 2 microns, and preferably between 100 and 300 Angstroms. However, a beneficial refractory metal layer may be quite thin, such as a layer applied by sputtering a flash coating, such as having a refractory metal layer having a thickness of between about 100 and about 200 Angstroms (Å). A suitable refractory metal may be selected from titanium (Ti), scandium (Sc), vanadium (V), chromium (Cr), manganese (Mn), yttrium (Y), zirconium (Zr), niobium (Nb), molybdenum (Mo), technetium (Tc), haffiium (Hf), tantalum (Ta), tungsten (W) and, rhenium (Re), combinations thereof, and alloys thereof.

In a further embodiment of the invention, a method of coating an evaporator boat comprises depositing a layer of a ceramic material over the evaporator boat formed of a different ceramic material. Preferably, the ceramic material of the deposited layer is more corrosion-resistant and wear-resistant than the ceramic of the evaporator boat body. In order to improve bonding of the ceramic layer to the ceramic evaporator boat, the method may further include depositing a layer of a refractory metal over the evaporator boat body before depositing the layer of ceramic material. The ceramic layer, and optionally also the refractory metal layer, are preferably deposited over at least the surface of a reservoir formed in the evaporator boat. Optionally, the ceramic layer is deposited by sputtering, the refractory metal layer is deposited by sputtering, or both. Flame spray and other coating techniques are less desirable because they may produce coatings that are too thick, not precise enough and/or tend to damage the boat. The thickness of the coating system should be monitored and limited so that the coating does not alter the thermal resistivity of the boat. Thermal resistivity may be measured, for example, in units of meters degrees Celsius per Watt (m° C./W), sometimes referred to as “MOC”.

It should be recognized that the coated evaporator boats may then be used in conventional or newly developed metallization processes. Such processes may include introducing a metal into the reservoir for contact with the ceramic layer; passing an electrical current through the evaporator boat to cause heating and evaporation of at least a portion of the metal.

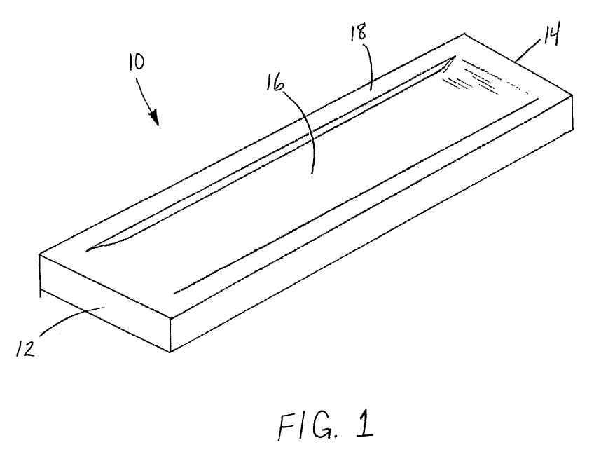

FIG. 1 is a perspective view of a ceramic evaporator boat 10. Electrical current is passed through the evaporator boat 10 from a first end 12 to a second end 14 to cause electrical resistance heating of the evaporator boat. A reservoir 16 is provided in the top surface of the boat 10 to receive and contain a metal. Desirably, the liquid metal puddle will extend over a large part of the reservoir 16 in order to evaporate metal at a desirable rate and avoid thermal gradients across the evaporator boat 10.

Although the coating embodiments of the invention may cover the entire evaporator boat, it is only critical to form the coating over the surfaces that would come in intimate contact with the molten metal, namely the reservoir 16. Because sputtering or certain other deposition techniques are directional, it may be preferably to coat essentially only the reservoir 16 or, alternatively, to coat essentially only the top surface 18 of the evaporator boat, which top surface includes the reservoir 16.

### EXAMPLE

Two prototypes of the coated evaporator boats were prepared in accordance with embodiments of the present invention and tested under identical conditions with several uncoated evaporator boats. The composition of each evaporator boat was identical and was identified to be about 75% boron nitride (BN) and about 25% titanium diboride (TiB₂). A first prototype was prepared by sputtering a refractory layer of chromium (Cr) over the reservoir of one of the evaporator boats to a thickness of 100 Angstroms, then sputtering a ceramic layer of titanium diboride (TiB₂) over the chromium layer to a thickness of 2 microns. A second prototype was prepared by sputtering a refractory layer of chromium (Cr) over the reservoir of another of the evaporator boats to a thickness of 100 Angstroms, then sputtering a ceramic layer of aluminum oxide (Al₂O₃) over the chromium layer to a thickness of 2 microns.

The two prototype evaporator boats and each of the uncoated evaporator boats were then tested in a vacuum metallization process by introducing aluminum into the reservoir of each boat. Electrical current was passed through each boat to cause evaporation of the aluminum until the boat reached one or more conditions indicating the end of the boat life. The uncoated evaporator boats were the first to fail, lasting between 8 and 12 hours each. The chromium/titanium diboride-coated prototype lasted for 19 hours and the chromium/aluminum oxide-coated prototype lasted for 21 hours. Failure of an evaporator boats was identified as the point when the boat either cracked or would no longer heat properly. Accordingly, the sputtered coatings were found to significantly increase boat life.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. An evaporator boat, comprising:
a boat body comprising an electrically conductive ceramic, wherein the boat body forms a reservoir for holding a puddle of liquid metal for evaporation; and
a ceramic layer formed over the reservoir surface, wherein the ceramic layer is formed of a ceramic material selected from metal borides, metal nitrides, metal carbides, metal oxides, and combinations thereof, and wherein the metal component of the ceramic material is selected from zirconium, aluminum, titanium, silicon, tantalum, vanadium, and combinations thereof.

2. The evaporator boat of claim 1, wherein the ceramic material is selected from aluminum oxide and titanium diboride.

3. The evaporator boat of claim 1, wherein the ceramic layer has an average thickness between 1.5 microns and 0.010 inches.

4. The evaporator boat of claim 1, wherein the electrically conductive ceramic of the boat body comprises boron nitride and titanium diboride.

5. The evaporator boat of claim 1, further comprising:
a refractory metal layer formed over a surface of the reservoir;

6. The evaporator boat of claim 5, wherein the refractory metal is selected from titanium, scandium, vanadium, chromium, manganese, yttrium, zirconium, niobium, molybdenum, technetium, haffiium, tantalum, tungsten, rhenium, combinations thereof, and alloys thereof.

7. The evaporator boat of claim 5, wherein the refractory metal is chromium.

8. The evaporator boat of claim 5, wherein the refractory metal layer is a flash coating.

9. The evaporator boat of claim 5, wherein the refractory metal layer has an average thickness between 100 Angstroms and 2 microns.

10. The evaporator boat of claim 5, wherein the refractory metal layer is formed by sputtering.

11. The evaporator boat of claim 5, wherein the refractory metal is chromium and the ceramic layer is selected from aluminum oxide and titanium diboride.

12. The evaporator boat of claim 11, wherein the electrically conductive ceramic of the boat body comprises boron nitride and titanium diboride.

13. The evaporator boat of claim 5, wherein the ceramic material is selected from aluminum oxide and titanium diboride.

14. The evaporator boat of claim 5, wherein the ceramic layer has an average thickness between 1.5 microns and 0.010 inches.

15. The evaporator boat of claim 5, wherein the electrically conductive ceramic of the boat body comprises boron nitride and titanium diboride.

16. A method comprising:
depositing a layer of a refractory metal over the surface of a reservoir formed in a ceramic evaporator boat; and
depositing a layer of a ceramic over the refractory metal layer.

17. The method of claim 16, wherein the ceramic layer is formed of a ceramic material selected from metal borides, metal nitrides, metal carbides, metal oxides, and combinations thereof, and wherein the metal component of the ceramic material is selected from zirconium, aluminum, titanium, silicon, tantalum, vanadium, and combinations thereof.

18. The method of claim 16, further comprising:
introducing a metal into the reservoir for contact with the ceramic layer; and
evaporating at least a portion of the metal.

19. The method of claim 16, wherein the refractory metal is selected from titanium, scandium, vanadium, chromium, manganese, yttrium, zirconium, niobium, molybdenum, technetium, haffiium, tantalum, tungsten, rhenium, combinations thereof, and alloys thereof.

20. The method of claim 16, wherein the refractory metal layer is formed by sputtering.

21. The method of claim 16, wherein the electrically conductive ceramic of the boat body comprises boron nitride and titanium diboride.

22. The method of claim 16, wherein the refractory metal is chromium.

23. The method of claim 16, wherein the ceramic material is selected from aluminum oxide and titanium diboride.
